(19) United States
(12) Patent Application Publication
(10) Pub. No.: US 2009/0095993 A1
(43) Pub. Date: Apr. 16, 2009

(54) SEMICONDUCTOR MEMORY DEVICE AND FABRICATING METHOD FOR SEMICONDUCTOR MEMORY DEVICE

(75) Inventors: Tohru Ozaki, Tokyo (JP); Yoshinori Kumura, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/244,210

(22) Filed: Oct. 2, 2008

(30) Foreign Application Priority Data
Oct. 10, 2007 (JP) 2007-264857

(51) Int. Cl. H01L 27/115; H01L 21/8246

(52) U.S. Cl. 257/295; 438/3; 257/E21.664; 257/E27.104

(57) ABSTRACT

According to an aspect of the present invention, there is provided a semiconductor memory device including a ferroelectric capacitor, including a semiconductor substrate, a transistor having diffusion layers being a source and a drain, the transistor being formed on a surface of the semiconductor substrate, a ferroelectric capacitor being formed over the transistor, the ferroelectric capacitor including a lower electrode, a ferroelectric film and an upper electrode stacked in order, an interlayer insulator separating between the transistor and the ferroelectric capacitor, a first contact plug being embedded in the interlayer insulator formed beneath the ferroelectric capacitor, the first contact plug directly connecting between one of the diffusion layers and the lower electrode, a first hydrogen barrier film covering the transistor a second hydrogen barrier film, a portion of the second hydrogen barrier film being formed on the first hydrogen barrier film, another portion of the second hydrogen barrier film covering at least the ferroelectric capacitor, and a second contact plug being embedded in the interlayer insulator, the second hydrogen barrier film and the first hydrogen barrier film, one end of the second contact plug connecting to the other of the diffusion layers.

### CROSS REFERENCE TO RELATED APPLICATION

This application is based upon and claims the benefit of priority from the prior Japanese Application (No. 2007-264857, filed Oct. 10, 2007), the entire contents of which are incorporated herein by reference.

### FIELD OF THE INVENTION

The present invention relates to a semiconductor memory device including a ferroelectric capacitor and fabricating method for the semiconductor memory device.

### DESCRIPTION OF THE BACKGROUND

Conventionally, a nonvolatile random access semiconductor memory using a ferroelectric capacitor (FeRAM) has been well known. In a series connected TC unite type ferroelectric RAM (hereafter, called a ferroelectric memory) as one kind of FeRAMs, neighboring transistors in a cell-array-block shares each other one diffusion layer. Furthermore, COP (Capacitor On Plug) structure as a ferroelectric capacitor aimed at miniaturization is used in FeRAMs. In the structure, a transistor is formed above a semiconductor substrate. A contact plug is embedded in an interlayer insulator formed above the transistor. The ferroelectric capacitor is formed on the contact plug.

In the ferroelectric memory, the transistor and the ferroelectric capacitor connected each other in parallel as a pair. The cell-array-block is constituted with a plurality of the pairs being serially connected each other. The ferroelectric capacitor is stacked with a lower electrode, a ferroelectric film and an upper electrode in order so that the ferroelectric capacitor is formed over the semiconductor substrate covered with an insulator.

Furthermore, characteristics of the ferroelectric capacitor are easily degraded by hydrogen reduction. Accordingly, the ferroelectric capacitor is covered with a hydrogen barrier film.

For example, Japanese Patent Publication (Kokai) No. 2005-268472 discloses a semiconductor memory device as described below in P4, P5 and FIG. 2. The semiconductor memory device is formed over a semiconductor substrate includes a transistor having a gate electrode and a pair of diffusion layers, a first interlayer insulator formed on the semiconductor substrate and the transistor, ferroelectric capacitor having a lower electrode, a ferroelectric film and an upper electrode in order selectively formed on the first interlayer insulator, a first hydrogen barrier film, a second hydrogen barrier film, a second interlayer insulator formed on the second hydrogen barrier film, a contact plug embedded through the second interlayer insulator, the second hydrogen barrier film the first hydrogen barrier film and the first interlayer insulator.

The first hydrogen barrier film includes a first portion, a second portion and a third portion continuously formed in order, the first portion being formed on the first interlayer insulator, the second portion covering a sidewall of the lower electrode, a sidewall of the ferroelectric film and a sidewall of the upper electrode, respectively, the third portion being formed on an upper surface of the upper electrode. The second hydrogen barrier film includes an intermediate layer formed on the second portion and on a fourth portion, a fifth portion and sixth portion continuously formed in order, the fourth portion including a contact portion contacted with at least a part of the first portion, the fifth portion being formed on the intermediate layer, the sixth portion being formed on the third portion.

However, the hydrogen barrier film is formed on the first interlayer insulator being on the transistor in the semiconductor memory device. The contact hole is formed through the second interlayer insulator, the second hydrogen barrier film, the first hydrogen barrier film and the first interlayer insulator. Accordingly, it is difficult to form the contact hole stably. Particularly, in the chain-type FeRAM structure using two-dimensional capacitor, a through hole is configured near the capacitor. Accordingly, it is extremely difficult to open a contact hole.

### SUMMARY OF INVENTION

According to an aspect of the present invention, there is provided a semiconductor memory device including a ferroelectric capacitor, including a semiconductor substrate, a transistor having diffusion layers being a source and a drain, the transistor being formed on a surface of the semiconductor substrate, a ferroelectric capacitor being formed over the transistor, the ferroelectric capacitor including a lower electrode, a ferroelectric film and an upper electrode stacked in order, an interlayer insulator separating between the transistor and the ferroelectric capacitor, a first contact plug being embedded in the interlayer insulator formed beneath the ferroelectric capacitor, the first contact plug directly connecting between one of the diffusion layers and the lower electrode, a first hydrogen barrier film covering the transistor a second hydrogen barrier film, a portion of the second hydrogen barrier film being formed on the first hydrogen barrier film, another portion of the second hydrogen barrier film covering at least the ferroelectric capacitor, and a second contact plug being embedded in the interlayer insulator, the second hydrogen barrier film and the first hydrogen barrier film, one end of the second contact plug connecting to the other of the diffusion layers.

Further, another aspect of the invention, there is provided, a semiconductor memory device including a ferroelectric capacitor, including a semiconductor substrate, a transistor including diffusion layers being a source and a drain on a surface of the semiconductor substrate, a gate insulator and a gate electrode, a ferroelectric capacitor being formed over the transistor, the ferroelectric capacitor including a lower electrode, a ferroelectric film and an upper electrode stacked in order, an interlayer insulator separating between the transistor and the ferroelectric capacitor, a first contact plug being embedded in the interlayer insulator formed beneath the ferroelectric capacitor, the first contact plug directly connecting between one of the diffusion layers and the lower electrode, a first hydrogen barrier film contacting to one of the diffusion layers and a portion of the gate insulator and the gate electrode near the one of the diffusion layers, a second hydrogen barrier film contacting to the other of the diffusion layers, a portion of the gate insulator and the gate electrode near the other of the diffusion layers and the ferroelectric capacitor, and a second contact plug embedded in the interlayer insulator and the second hydrogen barrier film, an end of the second contact plug connecting to the other of the diffusion layers.

Further, another aspect of the invention, there is provided, a method for fabricating a semiconductor memory device including a ferroelectric capacitor, including, a transistor having diffusion layers being a source and a drain on a semiconductor substrate, forming a first hydrogen barrier film to cover the transistor, forming a first interlayer insulator over the first hydrogen barrier film, forming a contact plug on one of the diffusion layers through the first interlayer insulator, forming a ferroelectric capacitor on the first interlayer insulator and the first contact plug, the ferroelectric capacitor including a lower electrode, a ferroelectric film and an upper electrode stacked in order, etching the first interlayer insulator using the ferroelectric capacitor as a mask, forming a second hydrogen barrier film to cover the ferroelectric capacitor, the first interlayer insulator and the first hydrogen barrier film, forming a second interlayer insulator on the second hydrogen barrier film, forming a second contact plug being embedded in the second interlayer insulator and the second hydrogen barrier film to connect to the upper electrode, and forming a third contact plug, the third contact plug being embedded in the second interlayer insulator, the second hydrogen barrier film and the first hydrogen barrier film to connect to the diffusion layer.

### BRIEF DESCRIPTION OF THE DRAWINGS

FIG. 1 is a cross-sectional schematic diagram showing a structure of a nonvolatile memory semiconductor device according to a first embodiment of the present invention;

FIGS. 2A-2C are cross-sectional schematic diagrams showing a method for fabricating the nonvolatile memory semiconductor device in order of processing steps according to the first embodiment of the present invention;

FIGS. 3A-3C are cross-sectional schematic diagrams showing the method for fabricating the nonvolatile memory semiconductor device in order of processing steps following FIGS. 2A-2C according to the first embodiment of the present invention;

FIGS. 4A-4C are cross-sectional schematic diagrams showing the method for fabricating the nonvolatile memory semiconductor device in order of processing steps following FIGS. 3A-3C according to the first embodiment of the present invention;

FIG. 5 is a cross-sectional schematic diagram showing a structure of a nonvolatile memory semiconductor device according to a second embodiment of the present invention;

FIG. 6 is a cross-sectional schematic diagram showing a structure of a nonvolatile memory semiconductor device according to a third embodiment of the present invention;

FIG. 7 is a cross-sectional schematic diagram showing a structure of a nonvolatile memory semiconductor device according to a fourth embodiment of the present invention;

FIG. 8 is a cross-sectional schematic diagram showing a structure of a nonvolatile memory semiconductor device according to a fifth embodiment of the present invention.

### DETAILED DESCRIPTION OF THE INVENTION

Embodiments of the present invention will be described below in detail with reference to the drawings mentioned above.

It is to be noted that the same or similar reference numerals are applied to the same or similar parts and elements throughout the drawings, and the description of the same or similar parts and elements will be omitted or simplified.

### First Embodiment

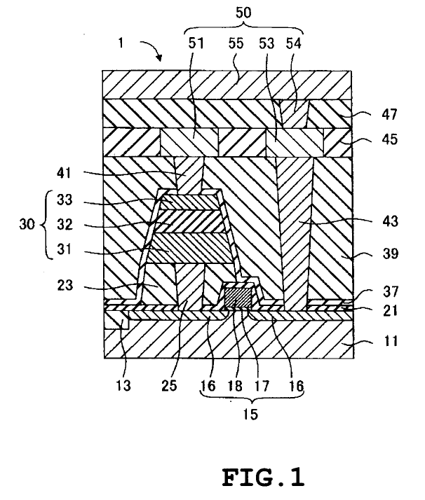

First, according to a first embodiment of the present invention, a semiconductor memory device and a method for fabricating the semiconductor memory device are explained with reference to FIGS. 1-4.

FIG. 1 is a cross-sectional schematic diagram showing a structure of a nonvolatile memory semiconductor device according to a first embodiment of the present invention.

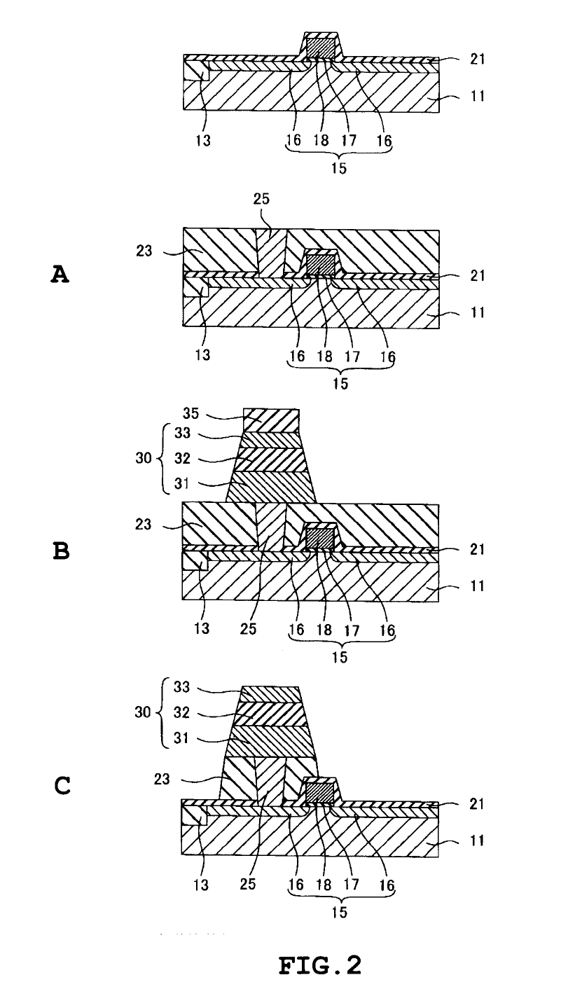

FIGS. 2A-2C are cross-sectional schematic diagrams showing a method for fabricating the nonvolatile memory semiconductor device in order of processing steps according to the first embodiment of the present invention.

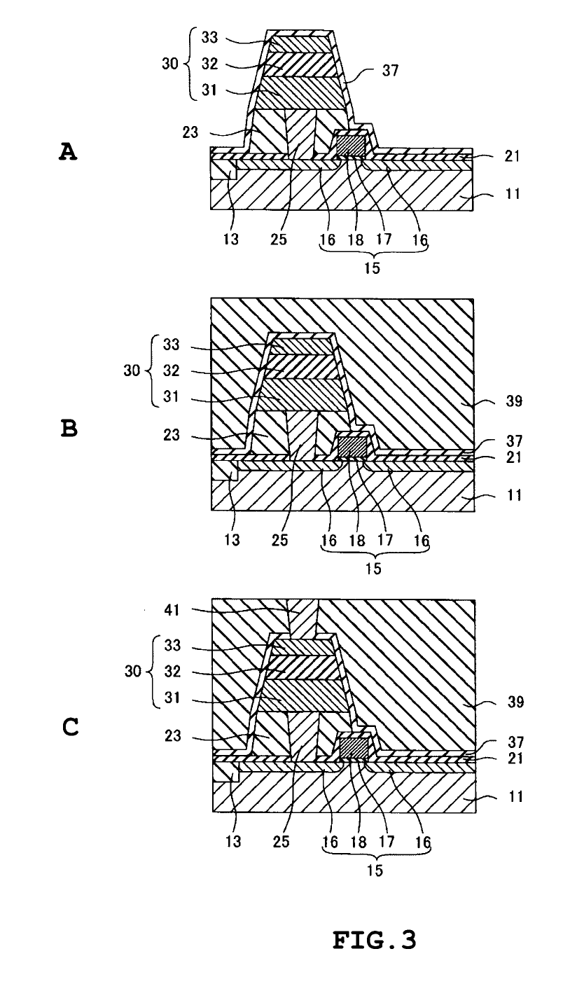

FIGS. 3A-3C are cross-sectional schematic diagrams showing the method for fabricating the nonvolatile memory semiconductor device in order of processing steps following FIGS. 2A-2C according to the first embodiment of the present invention.

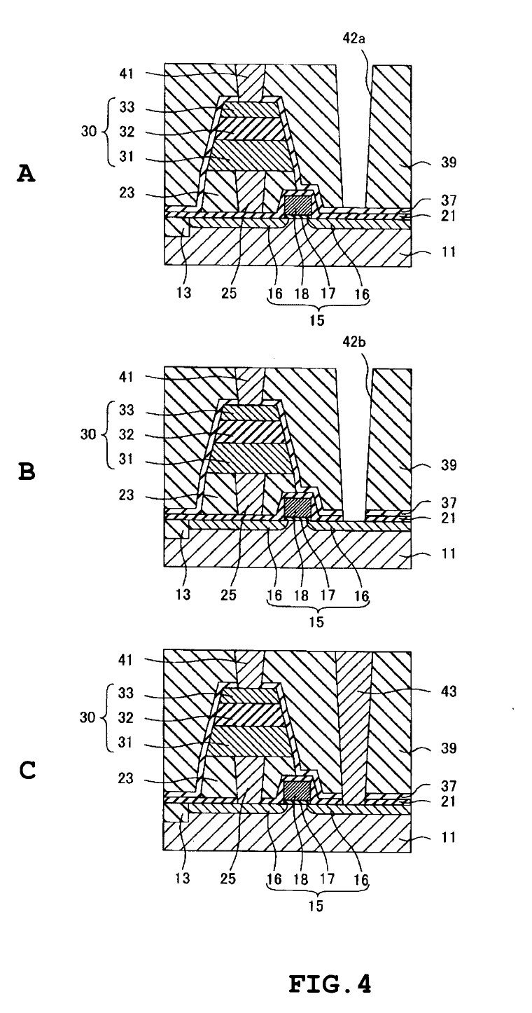

FIGS. 4A-4C are cross-sectional schematic diagrams showing the method for fabricating the nonvolatile memory semiconductor device in order of processing steps following FIGS. 3A-3C according to the first embodiment of the present invention.

As shown in FIG. 1, a semiconductor memory device 1 includes a semiconductor substrate 11, a transistor 15 formed on a surface of the semiconductor substrate 11, a ferroelectric capacitor 30 configured to an upper portion of the transistor 15, a wiring portion 50 configured to an upper portion of the ferroelectric capacitor 30, contact plugs 25,41 and 43 connecting to the transistor 15, the ferroelectric capacitor 30 and the wiring portion 50, respectively, and a lower hydrogen barrier film 21 and an upper hydrogen barrier film 37 protecting the ferroelectric capacitor 30.

In detail, a semiconductor memory device 1 is constituted with further many portions mentioned below. The transistor 15 includes diffusion layers 16 on a main surface of the semiconductor substrate 11 as a source and a drain. The contact plug 25 is embedded in an interlayer insulator 23 to be formed as a first contact plug and one end of the contact plug 25 is connected to one of the diffusion layers 16. The ferroelectric capacitor 30 is stacked a lower electrode 31, a ferroelectric film 32 and an upper electrode 33 in order. The lower electrode 31 is connected to the other end of the contact plug 25, and the upper electrode 33 is connected to a plate line 51 as a first wiring via the contact plug 41. The hydrogen barrier film 21 is formed as a first hydrogen barrier film to cover the transistor 15. The hydrogen barrier film 37 is formed as a second hydrogen barrier film to cover the ferroelectric capacitor 30 and the interlayer insulator 23 and to contact with the hydrogen barrier film 21 except a connecting portion of the upper electrode 33 to the contact plug 41. The contact plug 43 is embedded in the hydrogen barrier film 21 and the hydrogen barrier film 37 as a second contact plug. The one end of the contact plug 43 is connected to the other of diffusion layers 16 and the other end of the contact plug 43 is connected to the wiring 53 as a second wiring.

The semiconductor substrate 11, for example, a p-type silicon substrate has an element region. The element region is isolated by an element isolation region 13 on the main surface of the semiconductor substrate 11. The element region has the n-type diffusion layers 16 being apart from each other as the source and the drain in the transistor 15. A gate electrode 18 is formed on a portion between a pair of the diffusion layers 16 via a gate insulator 17. Furthermore, the hydrogen barrier film 21 is formed to cover the transistor 15 and other portion of the semiconductor substrate 11. Moreover, sidewall insulator or the like being formed at a sidewall of the gate electrode 18 is not illustrated.

The ferroelectric capacitor 30 is a layered structure being stacked with the lower electrode 31, the ferroelectric film 32 and the upper electrode 33 in order from the lower transistor 15. Sidewalls of the ferroelectric capacitor 30 are perpendicular or gradually sloping to the surface of the semiconductor substrate 11. The lower electrode 31 is connected to the one of the diffusion layers 16 in the transistor 15 via the contact plug 25. Furthermore, an upper surface of the lower electrode 31 has nearly the same area as the lower surface of the lower electrode 31 and the lower electrode 31 is disposed on the interlayer insulator 23 being perpendicular or gradually sloping to the surface of the semiconductor substrate 11.

The gate electrode 18 of the transistor 15 is disposed to perpendicularly lower direction of a lower sidewall of the lower electrode 31. Accordingly, a portion of sidewalls of the interlayer insulator 23 is contacted with the hydrogen barrier film 21 at the upper portion of the gate electrode 18.

The upper electrode 33 is connected to the plate wiring 51 via the contact plug 41. Furthermore, an upper-film being isolative may be formed over the upper electrode 33.

The hydrogen barrier film 37 is formed on an upper surface and the sidewall of the ferroelectric capacitor 30 except the upper surface where the contact plug 41 is embedded in the interlayer insulator 23 to contact the upper surface, the sidewall of the interlayer insulator 23 and the hydrogen barrier film 21. Accordingly, the ferroelectric capacitor 30 and the interlayer insulator 23 are covered with the hydrogen barrier film 37 and the hydrogen barrier film 21 without a space except the portion where the contact plug 41 is embedded in the interlayer insulator 23 to contact the upper surface of the ferroelectric capacitor 30. A stacked layer composed of the hydrogen barrier film 37 and the hydrogen barrier film 21 is configured on a portion where the ferroelectric capacitor 30 and the interlayer insulator 23 are not formed.

An interlayer insulator 39 is formed above the hydrogen barrier film 37. The plate line 51 and an interlayer insulator 45 are formed above the interlayer insulator 39 and a contact plug 54 and an interlayer insulator 47 are formed above the plate line 51 and the interlayer insulator 45. Moreover, the wiring portion 50 including a bit line 55 is constituted above the contact plug 54 and the interlayer insulator 47.

An upper end of the contact plug 43 is connected to the wiring 53, the contact plug 43 is embedded in the interlayer insulator 39, the hydrogen barrier film 37 and the hydrogen barrier film 21, and a lower end of the contact plug 43 is connected to the diffusion layer 16. Sidewalls of the interlayer insulator 39, the hydrogen barrier film 37 and the hydrogen barrier film 21 contacted with the sidewalls of the contact plug 43 is perpendicular or gradually sloping to the surface of the semiconductor substrate 11. Namely, the contact plug 43 is approximately a column or a spindle structure being narrowed towards to the lower portion. In detail, the contact plug 43 is uniformly the column structure in the interlayer insulator 39 or the spindle structure being narrowed towards to the lower portion. However, the contact plug 43 may has a spindle structure being narrower than the structure extended from the interlayer insulator 39 in the hydrogen barrier film 37 and the hydrogen barrier film 21. The contact plug 43 has not a connecting portion at halfway from the upper end portion to the lower end portion in both cases, as a result, the contact plug 43 is uniformly formed of a conductive material to connect the diffusion layer 16.

The upper end of the contact plug 25 is connected to the lower electrode 31, the contact plug 25 is embedded in the interlayer insulator 23 and the hydrogen barrier film 21, and a lower end of the contact plug 25 is connected to the diffusion layer 16. The contact plug 25 is formed in the interlayer insulator 23 to be narrower than the ferroelectric capacitor 30. The contact plug 25 has approximately the same shape as the contact plug 43 and the length of the contact plug 25 in direction from the upper end to the lower end is shorter than the length of the contact plug 43. As the hydrogen barrier film 21 is only one layer so that the contact plug 25 can be formed as a desired shape.

The upper end of the contact plug 41 is connected to the upper electrode 33, the contact plug 41 is embedded in the interlayer insulator 39 and the hydrogen barrier film 37, and the lower end of the contact plug 41 is connected to the plate line 51. The contact plug 41 is formed in the interlayer insulator 43 to be narrower than the ferroelectric capacitor 30. The contact plug 41 has approximately the same shape as the contact plug 43 and the length of the contact plug 41 in direction from the upper end to the lower end is shorter than the length of the contact plug 43. As the hydrogen barrier film 37 is only one layer so that the contact plug 41 can be formed as a desired shape.

Next, fabricating for the semiconductor memory device 1 is explained below. As shown in FIG. 2A, the transistor 15 is formed on the semiconductor substrate 11 by using well-known processing steps. The hydrogen barrier film 21 is formed to cover the transistor 15 including the diffusion layers 16, each of the diffusion layers 16 being the source and the drain, respectively, and the gate electrode 18, and another surface of the semiconductor substrate 11. The hydrogen barrier film 21 being used SiN or the like as a material is formed by P-CVD (Plasma enhanced Chemical Vapor Deposition) or the like, for example.

As shown in FIG. 2B, the interlayer insulator 23 is formed on the hydrogen barrier film 21. A contact hole (not illustrated) is formed on the interlayer insulator 23. A contact plug film being conductive is embedded in the contact by reflow-sputtering, MOCVD (Metal Organic CVD) or the like. Subsequently, the entire surface is flattened by CMP (Chemical Mechanical Polishing) or the like to form the contact plug 25. The interlayer insulator 23 for example, BPSG (Boron Phosphorous Silicate Glass) PSG, or P-TEOS film formed by P-CVD using TEOS (Tetra Ethoxy Silane) as a source gas. The contact plug film is constituted with, for example, W, Al, poly-crystalline silicon or the like. Furthermore, a conductive contact-reaction barrier metal film, for example, Ti, TiN or the like may be formed on the sidewall of the contact plug film for preventing the metal or the like being constituted with the contact plug film from diffusing into the diffusion layers 16 in the transistor 15.

As shown in FIG. 2C, on the interlayer insulator 23 and the contact plug 25, the lower electrode film 31, the ferroelectric film 32 and the upper electrode film 33 as materials constituting the ferroelectric capacitor 30 and a mask film being used as a processing mask are stacked in order. After forming mask film 35 by photo-lithography and RIE (Reactive Ion Etching), an electrode film and a ferroelectric film are delineated by RIE. As a result, ferroelectric capacitor 30 being constituted with the lower electrode 31, the ferroelectric film 32 and the upper electrode 33 is formed so that width of the ferroelectric capacitor 30 is wider with lowering portion. Furthermore, the mask film 35 is remained. The lower electrode film and the upper electrode film are constituted with a material including at least one of Pt, Ir, IrO₂, SRO(SrRuO₃), Ru, RuO₂ or the like, for example. The ferroelectric film is constituted with a material including at least one of PZT(Pb(Zr_{,} Ti)O₃), SBT(SrBi₂Ta₂O₉), PZLT((Pb, La)(Zr, Ti)O₃) or the like, for example. The mask is constituted with a material, for example, TEOS, Al₂O₃ TiAlN or the like.

As shown in FIG. 2D, the interlayer insulator 23 is removed using the mask film 35 as a mask and the ferroelectric capacitor 30 as a mask by RIE to expose the hydrogen barrier film 21. In this processing step, the mask film 35 on the ferroelectric capacitor 30 is removed. Moreover, the mask film can be remained, especially, as the mask film Al₂O₃, TiAlN or the like as the mask film may be remained on the upper electrode 33.

As shown in FIG. 3A, the hydrogen barrier film 37 is formed on the hydrogen barrier film 21, the interlayer insulator 23 and the ferroelectric capacitor 30 by sputtering, ALD (Atomic Layer Deposition) or the like, for example. The hydrogen barrier film 37 is constituted with Al₂O₃, SiN or the like, for example.

As shown in FIG. 3B, the interlayer insulator 39 is formed on the hydrogen barrier film 37 and flattened by CMP or the like. The interlayer insulator 39 can be formed by the same method as the interlayer insulator 23.

As shown in FIG. 3C, a contact hole is formed by using photo-lithography and RIE for a contact plug connecting with the upper electrode 33, subsequently, the contact plug 41 is formed. The contact plug 41 is flattened by CMP or the like as same as the contact plug 25.

As shown in FIG. 4A, the contact hole 42a is formed in the interlayer insulator 39 by using photo-lithography and RIE for forming a contact plug connecting with the diffusion layer 16. As an etching gas, CF or the like is used in the RIE technique.

As shown in FIG. 4B, the contact hole 42b is formed in the hydrogen barrier film 37 and the hydrogen barrier film 21 being a bottom of the contact hole 42a by RIE. As an etching gas, Cl or the like is used in the RIE technique. The contact hole 42b penetrates from the upper surface of the interlayer insulator 39 to the upper surface of the diffusion layer 16.

As shown in FIG. 4C, a conductive contact plug film is continuously formed in the contact hole 42b by reflow-sputtering, CVD or the like. Subsequently, the surface of the interlayer insulator 39 is flattened by CMP or the like to form the contact plug 43. The contact plug 43 is the same as the contact plug 25 mentioned above.

Finally, the interlayer insulators 45, 47 and the bit line 55 or the like is formed in order on the contact plugs 41,43 and the interlayer insulator 39 by a method for fabricating a conventional semiconductor memory device, as a result, the semiconductor memory device 1 is finished as shown in FIG. 1.

As mentioned above, the semiconductor memory device 1 includes the semiconductor substrate 11, the transistor 15 having the diffusion layers 16 formed on the surface of the semiconductor substrate 11, the ferroelectric capacitor 30 being configured to the upper portion of the transistor 15, the wiring portion 50 being configured to the upper portion of the ferroelectric capacitor 30, the contact plugs 25,41,43 connecting between the diffusion layers 16, the ferroelectric capacitor 30 and the wiring portion 50, respectively, and the lower hydrogen barrier film 21 and the upper hydrogen barrier film 37, each of the hydrogen barrier films protecting the ferroelectric capacitor 30. Particularly, the hydrogen barrier film 21, 37 being disposed between the upper interlayer insulator 39 and the surface of the semiconductor substrate 11 is opened to form the contact plug 43 connecting between the diffusion layer 16 and the wiring portion 50.

The contact hole used as the contact plug 43 can be comparatively easily formed perpendicular or gradually sloping to the surface of the semiconductor substrate in the BPSG or P-TEOS film as the interlayer insulator by using RIE. On the other hand, forming the contact hole by using RIE is difficult in the hydrogen barrier film, particularly, Al₂O₃ as the material, even if an etching gas is appropriately selected. Namely, etching rate of Al₂O₃ is extremely late to narrow the diameter of the contact hole. For example, the conventional semiconductor memory device disclosed in Japanese Patent Publication (Kokai) No. 2005-268472 has a stacked structure constituted with an upper interlayer insulator, a hydrogen barrier film and a lower interlayer insulator in order. Accordingly, forming a prescribed opening in the lower interlayer insulator is difficult through the intermediate hydrogen barrier film. The diameter of the contact hole is extremely narrowed to produce a faulty shape of the contact hole so that contact plug cannot obtain a desirable low resistance.

However, the diffusion layers 16 of the semiconductor memory device 1 are configured beneath the hydrogen barrier film 21 and the hydrogen barrier film 37. On the other hand, the conventional semiconductor memory device includes the lower interlayer insulator beneath the hydrogen barrier film to further continuously form the contact hole. Accordingly, an opening faulty is easily generated in the conventional semiconductor memory device by fluctuation in the processing conditions. On the contrary, tolerance of the diameter and the shape of the lower end in the contact hole 42b in the semiconductor memory device 1 is substantially widened so that decreasing a yield in the opening processing steps of the contact hole 42b in the semiconductor memory device 1 can be suppressed. Namely, the semiconductor memory device and the method of fabricating the semiconductor memory device including the contact plug suppressing the yield in the opening processing steps can be provided according to the invention as shown in the first embodiment.

Moreover, the diameter at the upper end of the interlayer insulator 39 or the like is not so wide for preventing the contact hole 42b in the semiconductor memory device 1 from being decreased with the opening yield so that a cell including the transistor 15, the ferroelectric capacitor 30 and the contact plug 43 can be highly integrated to miniaturize the semiconductor memory device 1.

Furthermore, the contact plug 43 in the semiconductor memory device 1 includes no connection portion where a contact plug film is discontinued at a midway between the upper end and the lower end. Therefore, the contact plug 43 is continuously formed from the upper surface of the diffusion layer 16 to the surface of the wiring portion 50. Accordingly, contact resistance in the connection portion is not increased to stably suppress the resistance of the contact plug 43.

Moreover, as the ferroelectric capacitor 30 of the semiconductor memory device 1 is protected by the lower hydrogen barrier film 21 and the upper hydrogen barrier film 37, penetration of hydrogen generated on the P-CVD process is reliably prevented. As a result, the semiconductor memory device 1 includes the ferroelectric capacitor 30 being suppressed on degradation of characteristics.

### Second Embodiment

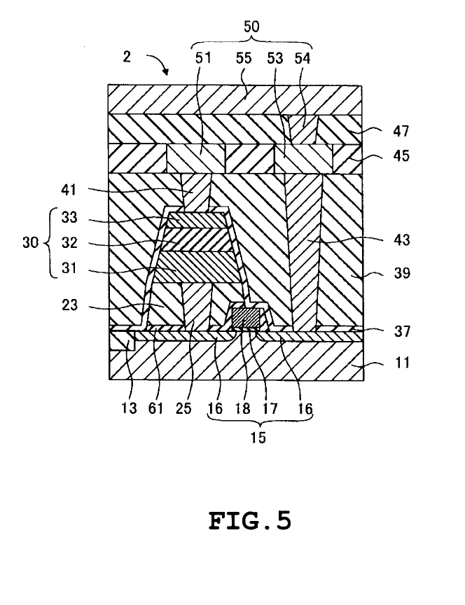

Next, according to a second embodiment of the present invention, a semiconductor memory device and a method for fabricating the semiconductor memory device are explained with reference to FIG. 5. FIG. 5 is a cross-sectional schematic diagram showing a structure of the nonvolatile memory semiconductor device according to the second embodiment of the present invention. Different points of the semiconductor memory device in the second embodiment as compared to the semiconductor memory device in the first embodiment are mentioned below, for example. A semiconductor memory device 2 as shown in FIG. 5 has a contact area, which is less as compared to that in the first embodiment, between a lower hydrogen barrier film and an upper hydrogen barrier film. In the second embodiment, a portion of a same composition as the first embodiment is attached the same number and explanation of the portion of the same composition is omitted.

With regard to this figure, the element similar to those described above with reference numerals and will not be described in detail.

As shown in FIG. 5, a hydrogen barrier film 61 in a semiconductor memory device 2 is configured beneath the interlayer insulator 23 as the same as the hydrogen barrier film 21 in the semiconductor memory device 1 of the first embodiment. The hydrogen barrier film 61 is not formed on another region. For example, on the upper surface of the gate electrode in the transistor 15, the hydrogen barrier film 61 is configured at a side of the contact plug 25. On the other hand, the hydrogen barrier film 37 is configured at a side of the contact plug 43 and the hydrogen barrier film 61 is contacted with the hydrogen barrier film 37. In other word, the ferroelectric capacitor 30 and the interlayer insulator 23 in the second embodiment are covered with the hydrogen barrier film 61 from the lower portion and the hydrogen barrier film 37 from the upper portion as the same as the semiconductor memory device 1 in the first embodiment. However, the other region except the ferroelectric capacitor 30 and the interlayer insulator 23 is covered with the hydrogen barrier film 37.

Next, a method for fabricating the semiconductor memory device 2 is explained below. First, processing steps in fabricating the semiconductor memory device 2 are proceeded from FIG. 2A to FIG. 2C as the same as the processing steps in fabricating the semiconductor memory device 1 of the first embodiment. Successive processing steps in fabricating the semiconductor memory device 2 are explained using FIG. 2D as a reference, for example. The hydrogen barrier film 61 without the interlayer insulator 23 thereon, for example, a portion on the gate electrode 18 and another surface of the semiconductor substrate 11 or the like is removed by RIE. Etching rate of the hydrogen barrier film 61 may be set to comparatively slow so as to lower an over-etching of the surface of the diffusion layer 16 as much as possible. Subsequently, processing steps in fabricating the semiconductor memory device 2 are proceeded from FIG. 3A to FIG. 4A as the same as the processing steps in fabricating the semiconductor memory device 1 of the first embodiment. FIG. 4A.

Successive processing steps in fabricating the semiconductor memory device 2 are explained using FIG. 4B as a reference, for example. A contact hole corresponding to the contact hole 42b opened in the hydrogen barrier film 37 being at the bottom of the contact hole 42a is formed by RIE. Etching rate of hydrogen barrier film 37 may be set to comparatively slow so as to lower an over-etching of the surface of the diffusion layer 16 as much as probable. The contact hole corresponding to the contact hole 42b is formed from an upper surface of the interlayer insulator 39 to an upper surface of the diffusion layer 16.

Subsequent processing steps is proceeded as the same as the processing steps in fabricating the semiconductor memory device 1 as shown in FIG. 4B-4C to complete the semiconductor memory device 2 as shown in FIG. 5. Furthermore, the hydrogen barrier film 61 may be composed of Al₂O₃ as a material having stronger hydrogen-barrier.

As mentioned above, the semiconductor memory device 2 has the same effects as the semiconductor memory device 1 in the first embodiment. Furthermore, as the hydrogen barrier film 37 is not stacked on the hydrogen barrier film 61, a fabricating yield due to adhesion faulty between the hydrogen barrier film 37 and the hydrogen barrier film 61 and peeling of the hydrogen barrier film 37 in post processing steps is suppressed. Moreover, as a lower end of the contact hole corresponding to the contact hole 42b is formed by only opening the hydrogen barrier film 37, lowering of an opening yield is more suppressed to enable to control the fabricating yield on the contact plug 43. Accordingly, the semiconductor memory device and the method for fabricating semiconductor memory device can be provided to suppress the decrease of the opening yield in the invention of the second embodiment.

### Third Embodiment

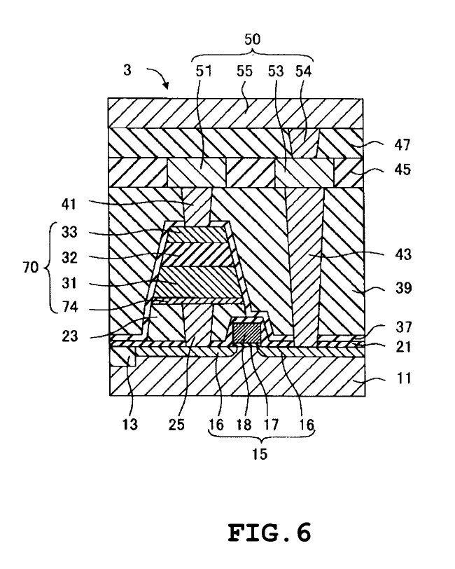

Next, according to a third embodiment of the present invention, a semiconductor memory device and a method for fabricating the semiconductor memory device are explained with reference to FIG. 6. FIG. 6 is a cross-sectional schematic diagram showing a structure of the nonvolatile memory semiconductor device according to the second embodiment of the present invention. Different points of the semiconductor memory device in the third embodiment as compared to the semiconductor memory device in the first embodiment are mentioned below, for example. A hydrogen barrier metal is formed in contact with a lower portion of a lower electrode in a semiconductor memory device 3 as shown in a FIG. 6. In the second embodiment, a portion of a same composition as the first embodiment is attached the same number and explanation of the portion of the same composition is omitted.

With regard to this figure, the element similar to those described above with reference numerals and will not be described in detail.

As shown in FIG. 6, a conductive hydrogen barrier metal 74 in the semiconductor memory device 3 is configured between the interlayer insulator 23 and the lower electrode 31. As a result, a ferroelectric capacitor 70 including the hydrogen barrier metal 74, the lower electrode 31, the ferroelectric film 32 and the upper electrode 33 is formed. The contact plug 25 is connected to the hydrogen barrier metal 74. Another portions are formed as the same as the semiconductor memory device 1 in the first embodiment.

Next, a method for fabricating the semiconductor memory device 3 is explained below. First, processing steps in fabricating the semiconductor memory device 3 are proceeded from FIG. 2A to FIG. 2B as the same as the processing steps in fabricating the semiconductor memory device 1 of the first embodiment. Successive processing steps in fabricating the semiconductor memory device 3 are explained using FIG. 2C as a reference, for example. The hydrogen barrier metal film is formed before depositing the lower electrode film and the lower electrode film, the ferroelectric film and the upper electrode film are successively stacked in order. The upper electrode film, the ferroelectric film, the lower electrode film and hydrogen barrier metal film are etched in order by RIE. The etching time or the like for hydrogen barrier metal film can be extended. The hydrogen barrier metal film is constituted with at least of conductive TiAlN, Ir, IrO₂, Ru, RuO₂ or the like, for example.

Subsequent processing steps are preceded as the same as the processing steps in fabricating the semiconductor memory device 1 as shown in FIG. 2C-4C to complete the semiconductor memory device 3 as shown in FIG. 6.

As mentioned above, the semiconductor memory device 3 has the same effects as the semiconductor memory device 1 in the first embodiment. Accordingly, the semiconductor memory device and the method for fabricating semiconductor memory device can be provided to suppress the decrease of opening yield in the invention of the third embodiment.

Furthermore, as the ferroelectric capacitor 30 is covered with the hydrogen barrier film 21 and the hydrogen barrier metal 74 from the lower side and the hydrogen barrier film 37 from the upper side, the ferroelectric capacitor 30 is protected against hydrogen penetration from the lower side. Consequently, the lower hydrogen barrier film 21 being thinner can be formed.

### Fourth Embodiment

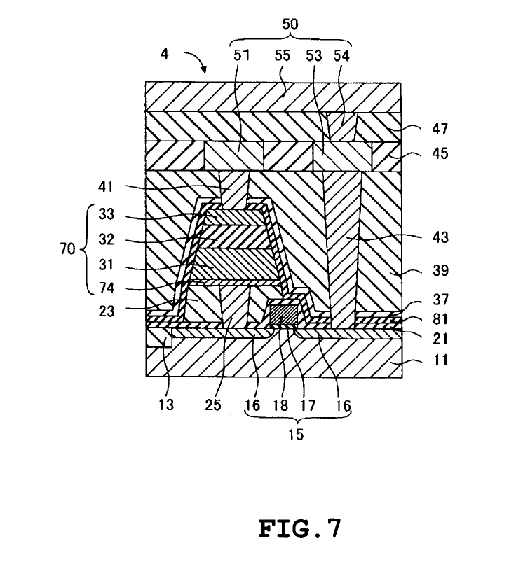

Next, according to a fourth embodiment of the present invention, a semiconductor memory device and a method for fabricating the semiconductor memory device are explained with reference to FIG. 7. FIG. 7 is a cross-sectional schematic diagram showing a structure of the nonvolatile memory semiconductor device according to the fourth embodiment of the present invention. Different points of the semiconductor memory device in the second embodiment as compared to the semiconductor memory device in the first embodiment and the third embodiment are mentioned below, for example.

A adhesion film having adhesiveness are additionally formed on a lower portion of an upper hydrogen barrier film and a portion between the upper hydrogen barrier film and the lower hydrogen barrier film in the semiconductor memory device 2 as shown in FIG. 5. In the fourth embodiment, a portion of a same composition as the first embodiment and the third embodiment is attached the same number and explanation of the portion of the same composition is omitted.

With regard to this figure, the element similar to those described above with reference numerals and will not be described in detail.

As shown in FIG. 7, an adhesion film 81 in a semiconductor memory device 4 as compared to the semiconductor memory device 3 in the third embodiment is additionally formed to contact with the ferroelectric capacitor 70, the interlayer insulator 23 and the hydrogen barrier film 21 on an inner side, and to contact with the hydrogen barrier film 37 on a lower side and on an outer side and an upper side. The ferroelectric capacitor 70 is covered with the hydrogen barrier film 37 and the adhesion film 81 from the upper side and is protected by the hydrogen barrier film 21 and the hydrogen barrier metal 74 from the lower side. The contact plug 43 is formed through the hydrogen barrier film 37, the adhesion film 81 and the hydrogen barrier film 21 of the three layers.

Next, a method for fabricating the semiconductor memory device 4 is explained below. The processing steps in fabricating the semiconductor memory device 4 are proceeded to the step as shown in FIGS. 2A-2C as the same as the processing steps in the semiconductor memory device 1 of the first embodiment. Successive processing steps in fabricating the semiconductor memory device 4 are explained using FIG. 3A as a reference, for example. The adhesion film 81 is formed on the hydrogen barrier film 21, the interlayer insulator 23 and the ferroelectric capacitor 70 instead of the ferroelectric capacitor 30 by sputtering, ALD or the like. The adhesion film 81 is constituted with TiO₂ or the like having the hydrogen barrier and the insulating performance as a material. Subsequently, the hydrogen barrier film 37 is formed to cover the adhesion film 81.

Subsequent processing steps are preceded as the same as the processing steps in fabricating the semiconductor memory device 1 as shown in FIG. 3B. Next processing steps in fabricating the semiconductor memory device 4 are explained using FIG. 3C as a reference, for example. A contact hole for forming a contact plug being connected with the upper electrode 33 is formed through the hydrogen barrier film 37 and the adhesion film 81 by photo-lithography and RIE. Subsequently, the contact plug 41 is formed.

Subsequent processing steps are preceded as the same as the processing steps in fabricating the semiconductor memory device 1 as shown in FIG. 4A. Next processing steps in fabricating the semiconductor memory device 4 are explained using FIG. 4B as a reference, for example. The hydrogen barrier film 37, the adhesion film 81 and the hydrogen barrier film 21 formed on the bottom of the contact hole 42a is opened by RIE to form a contact hole corresponding to the contact hole 42b. The etching gas used in the RIE is Cl-system. The contact hole corresponding to the contact hole 42b is formed from the upper surface of the interlayer insulator 39 to the upper surface of the diffusion layer 16.

Subsequent processing steps are preceded as the same as the processing steps in fabricating the semiconductor memory device 1 as shown in FIG. 4B-4C to complete the semiconductor memory device 4 as shown in FIG. 7.

As mentioned above, the semiconductor memory device 4 has the same effects as the semiconductor memory device 1 in the first embodiment and the semiconductor memory device 3 in the third embodiment.

Furthermore, as the hydrogen barrier film 37 is stacked on the hydrogen barrier film 81, a fabricating yield due to adhesion faulty between the hydrogen barrier film 37 and the hydrogen barrier film 81 and peeling of the hydrogen barrier film 37 in post processing steps is suppressed. Accordingly, the semiconductor memory device and the method for fabricating semiconductor memory device can be provided to suppress the decrease of the opening yield in the invention of the fourth embodiment.

Moreover, as an upper surface of the gate electrode is not exposed in the semiconductor memory device 4 as compared to the structure of the semiconductor memory device 2 in the second embodiment, accumulation of plasma charges to the gate electrode in RIE process is suppressed so that damage of the gate insulator 17 is suppressed.

### Fifth Embodiment

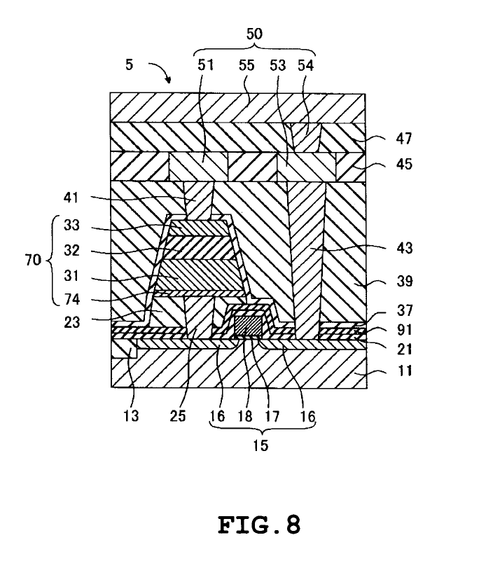

Next, according to a fifth embodiment of the present invention, a semiconductor memory device and a method for fabricating the semiconductor memory device are explained with reference to FIG. 8. FIG. 8 is a cross-sectional schematic diagram showing a structure of the nonvolatile memory semiconductor device according to the fifth embodiment of the present invention. Different points of the semiconductor memory device in the fifth embodiment as compared to the semiconductor memory device in the first embodiment, the third embodiment and the fourth embodiment are mentioned below, for example.

The adhesion film having adhesiveness is additionally formed on the lower hydrogen barrier film in the semiconductor memory device 5 as shown in FIG. 8. In the fifth embodiment, a portion of a same composition as the first embodiment, the third embodiment and fourth embodiment is attached the same number and explanation of the portion of the same composition is omitted.

With regard to this figure, the element similar to those described above with reference numerals and will not be described in detail.

As shown in FIG. 8, an adhesion film 91 in a semiconductor memory device 5 as compared to the semiconductor memory device 3 in the third embodiment is additionally formed to contact with the hydrogen barrier film 21 on an inner side and a lower side, and to contact with the interlayer insulator 23 and the hydrogen barrier film 37. A ferroelectric capacitor 70 is covered with the hydrogen barrier film 37 from the upper side and is protected by the hydrogen barrier film 21, an adhesion film 91 and the hydrogen barrier metal 74 from the lower side. The contact plug 43 is formed through the hydrogen barrier film 37, the adhesion film 91 and the hydrogen barrier film 21 of the three layers.

Next, a method for fabricating the semiconductor memory device 5 is explained below. The processing steps in fabricating the semiconductor memory device 5 are proceeded to the step as shown in FIG. 2A as the same as the processing steps in the semiconductor memory device 1 of the first embodiment. Successive processing steps in fabricating the semiconductor memory device 5 are explained using FIG. 2A as a reference, for example. The adhesion film 91 is formed on the hydrogen barrier film 21 by sputtering, ALD or the like, for example. The adhesion film 91 is constituted with TiO₂ or the like. Subsequently, the interlayer insulator 23 is formed to cover the adhesion film 91.

Successive processing steps in fabricating the semiconductor memory device 5 are explained using FIG. 2B as a reference, for example. A contact hole for forming a contact plug being connected to the diffusion layer 16 and the hydrogen barrier metal 74 is formed through the adhesion film 91 and the hydrogen barrier film 21 by photo-lithography and RIE. Next, the contact plug 25 is formed.

Subsequent processing steps in fabricating the semiconductor memory device 5 are proceeded to the step as shown in FIGS. 2C-4A as the same as the processing steps in the semiconductor memory device 1 of the first embodiment. Successive processing steps in fabricating the semiconductor memory device 5 are explained using FIG. 4B as a reference, for example. The hydrogen barrier film 37, the adhesion film 81 and the hydrogen barrier film 21 formed on the bottom of the contact hole 42a is opened by RIE to form a contact hole corresponding to the contact hole 42b. The etching gas used the RIE is Cl-system. The contact hole corresponding to the contact hole 42b is formed from the upper surface of the interlayer insulator 39 to the upper surface of the diffusion layer 16.

Subsequent processing steps is proceeded as the same as the processing steps in fabricating the semiconductor memory device 1 as shown in FIG. 4C to complete the semiconductor memory device 5 as shown in FIG. 8.

As mentioned above, the semiconductor memory device 5 has the same effects as the semiconductor memory device 1 in the first embodiment and the semiconductor memory device 3 in the third embodiment.

Furthermore, as the hydrogen barrier film 37 is stacked on the hydrogen barrier film 21, a fabricating yield due to adhesion faulty between the hydrogen barrier film 37 and the hydrogen barrier film 21 and peeling of the hydrogen barrier film 37 in post processing steps is suppressed. Accordingly, the semiconductor memory device and the method for fabricating semiconductor memory device can be provided to suppress the decrease of the opening yield in the invention of the fifth embodiment.

Moreover, as a metal with high reduction capability composed of TiO₂ or the like is formed not to contact with the ferroelectric film 32 in the semiconductor memory device 5 as compared to the structure of the semiconductor memory device 4 in the fourth embodiment, degradations of polarization characteristics and polarization retaining characteristics can be suppressed. Accordingly, phenomena as mentioned below are decreased in the semiconductor memory device 5. Excess metals with high reduction capability in a post thermal process, which is approximately performed in a range of 300° C.-500° C., deprive oxygen from a sidewall of the ferroelectric film 32 composed of PZT or the like to generate oxygen loss.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the claims that follow. The invention can be carried out by being variously modified within a range not deviated from the gist of the invention.

For example, the ferroelectric capacitor including the hydrogen barrier metal and the hydrogen barrier film additionally having adhesion layer are combined. However, a ferroelectric capacitor without the hydrogen barrier metal and the hydrogen barrier film additionally having adhesion layer also can be combined.

What is claimed is:

1. A semiconductor memory device including a ferroelectric capacitor, comprising:
a semiconductor substrate;
a transistor having diffusion layers being a source and a drain, the transistor being formed on a surface of the semiconductor substrate;
a ferroelectric capacitor being formed over the transistor, the ferroelectric capacitor including a lower electrode, a ferroelectric film and an upper electrode stacked in order;
an interlayer insulator separating between the transistor and the ferroelectric capacitor;
a first contact plug being embedded in the interlayer insulator formed beneath the ferroelectric capacitor, the first contact plug directly connecting between one of the diffusion layers and the lower electrode;
a first hydrogen barrier film covering the transistor;
a second hydrogen barrier film, a portion of the second hydrogen barrier film being formed on the first hydrogen barrier film, another portion of the second hydrogen barrier film covering at least the ferroelectric capacitor; and
a second contact plug being embedded in the interlayer insulator, the second hydrogen barrier film and the first hydrogen barrier film, one end of the second contact plug connecting to the other of the diffusion layers.

2. The semiconductor memory device including the ferroelectric capacitor according to claim 1, further comprising;
a hydrogen barrier metal contacting a first surface of the lower electrode and the first contact plug.

3. The semiconductor memory device including the ferroelectric capacitor according to claim 2,
wherein the hydrogen barrier metal includes at least one of TiAlN, Ir, IrO₂, Ru and RuO₂, or a stacked layer of a TiAlN layer and another layer at least including one of TiAlN, Ir, IrO₂, Ru and RuO₂.

4. The semiconductor memory device including the ferroelectric capacitor according to claim 1, further comprising;
an adhesion film being included between the first hydrogen barrier film and the second hydrogen barrier film.

5. The semiconductor memory device including the ferroelectric capacitor according to claim 4,
wherein the adhesion film is formed at least between the ferroelectric capacitor and the first hydrogen barrier film.

6. The semiconductor memory device including the ferroelectric capacitor according to claim 4,
wherein the adhesion film is formed at least between the transistor and the second hydrogen barrier film.

7. The semiconductor memory device including the ferroelectric capacitor according to claim 4,
wherein the adhesion film includes at least TiO₂ having hydrogen barrier performance and insulating performance.

8. A semiconductor memory device including a ferroelectric capacitor, comprising:
a semiconductor substrate,
a transistor including diffusion layers being a source and a drain on a surface of the semiconductor substrate, a gate insulator and a gate electrode;
a ferroelectric capacitor being formed over the transistor, the ferroelectric capacitor including a lower electrode, a ferroelectric film and an upper electrode stacked in order;
an interlayer insulator separating between the transistor and the ferroelectric capacitor;
a first contact plug being embedded in the interlayer insulator formed beneath the ferroelectric capacitor, the first contact plug directly connecting between one of the diffusion layers and the lower electrode;
a first hydrogen barrier film contacting to one of the diffusion layers and a portion of the gate insulator and the gate electrode near the one of the diffusion layers;
a second hydrogen barrier film contacting to the other of the diffusion layers, a portion of the gate insulator and the gate electrode near the other of the diffusion layers and the ferroelectric capacitor; and
a second contact plug embedded in the interlayer insulator and the second hydrogen barrier film, an end of the second contact plug connecting to the other of the diffusion layers.

9. The semiconductor memory device including the ferroelectric capacitor according to claim 8, further comprising;
a hydrogen barrier metal contacting a first surface of the lower electrode and the first contact plug.

10. The semiconductor memory device including the ferroelectric capacitor according to claim 9,
wherein the hydrogen barrier metal includes at least one of TiAlN, Ir, IrO₂, Ru and RuO₂, or a stacked layer of a TiAlN layer and another layer at least including one of TiAlN,Ir,IrO₂,Ru and RuO₂.

11. The semiconductor memory device including the ferroelectric capacitor according to claim 8,
wherein the adhesion film is formed at least between the transistor and the second hydrogen barrier film.

12. The semiconductor memory device including the ferroelectric capacitor according to claim 11,
wherein the adhesion film includes at least TiO₂ having hydrogen barrier performance and insulating performance.

13. A method for fabricating a semiconductor memory device including a ferroelectric capacitor, comprising;
a transistor having diffusion layers being a source and a drain on a semiconductor substrate;
forming a first hydrogen barrier film to cover the transistor;
forming a first interlayer insulator over the first hydrogen barrier film;
forming a contact plug on one of the diffusion layers through the first interlayer insulator;
forming a ferroelectric capacitor on the first interlayer insulator and the first contact plug, the ferroelectric capacitor including a lower electrode, a ferroelectric film and an upper electrode stacked in order;
etching the first interlayer insulator using the ferroelectric capacitor as a mask;
forming a second hydrogen barrier film to cover the ferroelectric capacitor, the first interlayer insulator and the first hydrogen barrier film;
forming a second interlayer insulator on the second hydrogen barrier film;
forming a second contact plug being embedded in the second interlayer insulator and the second hydrogen barrier film to connect to the upper electrode; and
forming a third contact plug, the third contact plug being embedded in the second interlayer insulator, the second hydrogen barrier film and the first hydrogen barrier film to connect to the diffusion layer.

14. The method for fabricating the semiconductor memory device including the ferroelectric capacitor according to claim 13, further comprising;
etching the first hydrogen barrier film between etching the first interlayer insulator and forming the second hydrogen barrier film.

15. The method for fabricating the semiconductor memory device including the ferroelectric capacitor according to claim 13, further comprising;
forming a hydrogen barrier metal in forming the ferroelectric capacitor, the hydrogen barrier metal contacting a first surface of the lower electrode and the first contact plug.

16. The method for fabricating the semiconductor memory device including the ferroelectric capacitor according to claim 15,
wherein the hydrogen barrier metal includes at least one of TiAlN, Ir, IrO₂, Ru and RuO₂, or a stacked layer of a TiAlN layer and another layer at least including one of TiAlN, Ir, IrO₂, Ru and RuO₂.

17. The method for fabricating the semiconductor memory device including the ferroelectric capacitor according to claim 13, further comprising;
forming a adhesion film between etching the first interlayer insulator and forming the second hydrogen barrier film; and
forming the third contact plug, the third contact plug being embedded further in the adhesion film.

18. The semiconductor memory device including the ferroelectric capacitor according to claim 17,
wherein the adhesion film includes at least TiO₂ having hydrogen barrier performance and insulating performance.

19. The method for fabricating the semiconductor memory device including the ferroelectric capacitor according to claim 13, further comprising;
forming the adhesion film between forming the first hydrogen barrier film and forming the first interlayer insulator; and
forming the third contact plug, the third contact plug being embedded further in the adhesion film.

20. The semiconductor memory device including the ferroelectric capacitor according to claim 19,
wherein the adhesion film includes at least TiO₂ having hydrogen barrier performance and insulating performance.
